(19) United States
(12) Patent Application Publication
(10) Pub. No.: US 2015/0000844 A1
(43) Pub. Date: Jan. 1, 2015

(54) MULTIPLE-MODE PLASMA GENERATION APPARATUS

(71) Applicant: EQBESTECH INC., Gyeonggi-do (KR)

(72) Inventor: Je-Ho Woo, Daejeon (KR)

(73) Assignee: EQBESTECH INC., Gyeonggi-do (KR)

(21) Appl. No.: 14/373,001

(22) PCT Filed: Jan. 16, 2013
(86) PCT No.: PCT/KR2013/000315

§ 371 Date: Jul. 17, 2014

(30) Foreign Application Priority Data
Jan. 17, 2012 (KR) 10-2012-0005247

(51) Int. Cl. H01J 37/32; H01L 21/67

(52) U.S. Cl. CPC H01J 37/32165; H01L 21/67069; H01J 37/32091; H01J 37/32183; H01J 2237/3321; H01J 2237/334; H01J 2237/335
USPC 156/345.38; 118/723 MP; 315/111.41

(57) ABSTRACT

The present invention relates to a multiple-mode plasma generation apparatus that can supply plasma for multiple processes in order to improve processing efficiency. The plasma generation apparatus may include a first plasma generation unit and a second plasma generation unit connected in series with the first plasma generation unit. Here, a gas is changed to plasma by a magnetic field generated by the first plasma generation unit and the second plasma generation unit, the first plasma generation unit is operated by a low-frequency power supply, and the second plasma generation unit is operated by a high-frequency power supply.

### CROSS-REFERENCE TO RELATED APPLICATIONS

This application is a National Phase Application of PCT International Application No. PCT/KR2013/000315, which was filed on Jan. 16, 2013, and which claims priority from Korean Patent Application No. 10-2012-0005247 filed with the Korean Intellectual Property Office on Jan. 17, 2012. The disclosures of the above patent applications are incorporated herein by reference in their entirety.

### BACKGROUND

1. Technical Field

The present invention relates to a plasma generation apparatus that supplies plasma to a semiconductor processing chamber.

2. Description of the Related Art

A semiconductor fabrication process may employ a large amount of plasma, for which a plasma supply apparatus may be used to supply plasma to the processing chamber. Of course, it is also possible to supply a gas into the processing chamber and change the gas to a plasma inside the processing chamber.

Generally, the plasma supply apparatus may be used only for a particular process, and for another process, another plasma supply apparatus may be used. For example, a plasma supply apparatus used in an etching process may be different a plasma supply apparatus used in a cleaning process. Thus, the efficiency of the processes may be degraded.

Also, a single-principle plasma source may provide low efficiency, such as in terms of decomposition rate and ionization rate, and may entail instability during the initial states of plasma generation according to the type and flow of the gas, so that a high-voltage plug such as an ignition plug may have to be installed.

### SUMMARY

An aspect of the invention is to provide a multiple-mode plasma generation apparatus that is capable of supplying plasma in multiple processes to improve processing efficiency.

To achieve the objective above, an embodiment of the invention provides a multiple-mode plasma generation apparatus for supplying a plasma to a processing chamber, where the multiple-mode plasma generation apparatus includes: a first plasma generation unit and a second plasma generation unit connected in series with the first plasma generation unit. Here, a gas is changed to plasma by a magnetic field generated by the first plasma generation unit and the second plasma generation unit, the first plasma generation unit is operated by a low-frequency power supply, and the second plasma generation unit is operated by a high-frequency power supply.

Another embodiment of the invention provides a multiple-mode plasma generation apparatus for supplying a plasma to a processing chamber, where the multiple-mode plasma generation apparatus includes: a first plasma generation unit and a second plasma generation unit connected in series with the first plasma generation unit. Here, a gas is changed to plasma by a magnetic field generated by the first plasma generation unit and the second plasma generation unit, and the working pressure of the first plasma generation unit is different from the working pressure of the second plasma generation unit.

Yet another embodiment of the invention provides a multiple-mode plasma generation apparatus for supplying a plasma to a processing chamber, where the multiple-mode plasma generation apparatus includes a plasma chamber, a first plasma generation unit, and a second plasma generation unit connected in series with the first plasma generation unit. Here, a gas is changed to plasma by a magnetic field generated by the first plasma generation unit and the second plasma generation unit, the first plasma generation unit is implemented in the form of an induction coil wound around a ferrite core in a middle portion of the plasma chamber, and the second plasma generation unit is implemented in the form of an induction coil wound around a plasma tube in an end portion of the plasma chamber.

Still another embodiment of the invention provides a multiple-mode plasma generation apparatus for supplying a plasma to a processing chamber, where the multiple-mode plasma generation apparatus includes a plasma chamber, a first plasma generation unit, and a second plasma generation unit connected in series with the first plasma generation unit. Here, a gas is changed to plasma by a magnetic field generated by the first plasma generation unit and the second plasma generation unit, plasma generated by a power supply applied to the second plasma generation unit is diffused into the plasma chamber for the ignition for the multiple-mode plasma generation apparatus, a plasma generation by the first plasma generation unit is activated by the diffused plasma, and there is no separate ignition element present for the first plasma generation unit.

A multiple-mode plasma generation apparatus according to an embodiment of the invention employs plasma generation units connected in series that are used with different frequencies or working pressures, making it possible to adequately supply plasma suited for multiple processes.

Also, for the ignition of the plasma generation apparatus, the plasma generation by the first plasma generation unit may be activated by the diffusion into the plasma chamber of the plasma generated by providing a high-frequency power supply to the second plasma generation unit. Thus, no separate ignition element is required for the first plasma generation unit.

Additional aspects and advantages of the present invention will be set forth in part in the description which follows, and in part will be obvious from the description, or may be learned by practice of the invention.

### BRIEF DESCRIPTION OF THE DRAWINGS

FIG. 1A and FIG. 1B illustrate a semiconductor process system using plasma according to an embodiment of the invention.

FIG. 2 illustrates a plasma generation apparatus according to an embodiment of the invention.

FIG. 3 illustrates a matching unit according to an embodiment of the invention.

### DETAILED DESCRIPTION

As the present invention allows for various changes and numerous embodiments, particular embodiments will be illustrated in the drawings and described in detail in the written description. However, this is not intended to limit the present invention to particular modes of practice, and it is to be appreciated that all changes, equivalents, and substitutes that do not depart from the spirit and technical scope of the present invention are encompassed in the present invention. In describing the drawings, like reference numerals are used for like elements. Certain embodiments of the invention are described below in more detail with reference to the appended drawings.

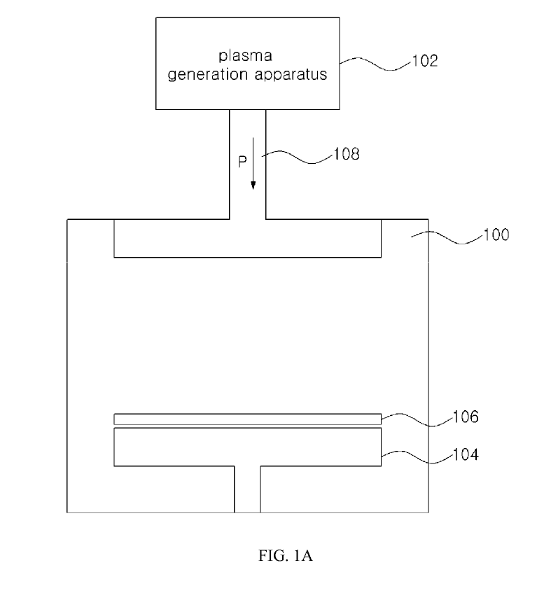

FIG. 1A and FIG. 1B illustrate a semiconductor process system using plasma according to an embodiment of the invention.

Referring to FIG. 1A, a semiconductor process system may perform various processes, such as a deposition (Chemical Vapor Deposition, CVD) process, an etching process, a cleaning process, etc., and may include a process chamber 100 and a plasma generation apparatus 102.

During a deposition process and an etching process, the plasma generated from the plasma generation apparatus 102 can be supplied through a supply pipe 108 to the process chamber 100, and by using the plasma thus supplied, a particular layer can be deposited or etched on a wafer positioned on a support part 104. Also, plasma can be supplied from the plasma generation apparatus 102 to the process chamber 100 to perform a cleaning process. That is, a plasma generation apparatus 102 according to an embodiment of the invention may supply plasma that can be used to perform at least two of multiple processes, such as a deposition process, an etching process, and a cleaning process, within the same process chamber 100. Of course, the gas changed into plasma can be different for each process. Examples of such gases can include NH₃, N₂, O₂, H₂, SiO₂, etc.

Whereas a conventional semiconductor process system uses a different plasma generation apparatus for each process, a semiconductor process system according to an embodiment of the invention can perform multiple processes using the same plasma generation apparatus 102. Therefore, a semiconductor process system according to an embodiment of the invention can provide greater utility and can reduce process costs.

The plasma generation apparatus 102 can include a first plasma generation unit 110 and a second plasma generation unit 112, as illustrated in FIG. 1B. Here, the first plasma generation unit 110 can operate with a low-frequency power supply, and the second plasma generation unit 112 can operate with a high-frequency power supply. Also, the plasma generation apparatus 102 can include three or more plasma generation units. However, the plasma generation units 110 and 112 can be designed with differences in at least one of the operating condition, frequency, and pressure. That is, the plasma generation apparatus 102 may be a multiple-mode plasma generation source.

According to an embodiment of the invention, the first plasma generation unit 110 can employ a ferrite core induction method using a low-frequency power supply that can be used in a working pressure range of about several Torr, while the second plasma generation unit 112 can employ an inductively coupled plasma method using a high-frequency power supply that can be used in a working pressure range of about several mTorr to several hundred mTorr. In particular, even though the first plasma generation unit 110 employs a plasma generation method that cannot be used in a working pressure range of several mTorr to several hundred mTorr and the second plasma generation unit 112 employs a plasma generation method that cannot be used in a high pressure range of several Torr to several tens of Torr, the plasma generation apparatus 102 can generate plasma within a broad range of working pressure from several mTorr to several tens of Torr by using the plasma generation units 110 and 112 having different operating properties. Thus, the plasma generation apparatus 102 can be used for multiple processes, such as the deposition process, etching process, and cleaning process, which have different processing conditions. Of course, a plasma generation unit 110 or 112 can also use other methods, such as the CCP (capacitively coupled plasma)-RIE (reactive ion etching) method in which a wafer is arranged at the point where an RF voltage is applied, the CCP-MERIE (magnetically enhanced RIE) method which is a variation of the RIE method and which involves applying a magnetic field in a plasma space to increase the probability of ion generation for etching, the ECR (electron cyclotron resonance) method in which microwave frequencies are used to generate resonance for ionizing neutral particles, the TCP (transformer coupled plasma) method which uses an RF coil with the coil wound only at an upper part of the processing chamber, the ICP (inductively coupled plasma) method which uses an RF coil with the coil wound at a side part of the processing chamber, the helical plasma method which uses an RF coil in a helical form, the HDP (high density plasma) method in which the part for generating plasma and the part for adjusting the ionization energy are controlled independently, and the like.

According to an embodiment of the invention, the supply gas may be changed to plasma by a magnetic field generated by the first plasma generation unit 110 and the second plasma generation unit 112.

The detailed structure of a plasma generation apparatus 102 according to an embodiment of the invention is described below with reference to the accompanying drawings.

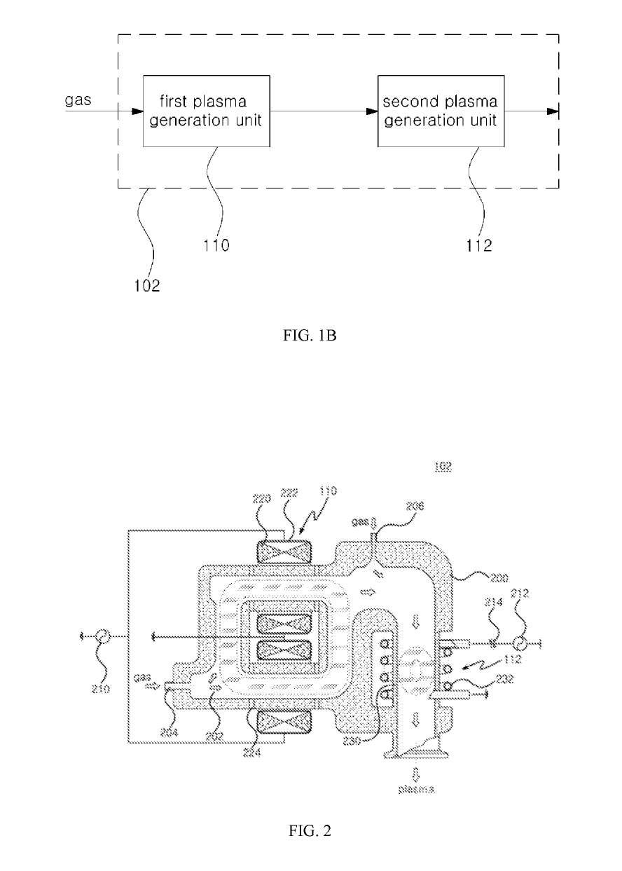

FIG. 2 illustrates a plasma generation apparatus according to an embodiment of the invention.

Referring to FIG. 2, a plasma generation apparatus 102 based on this embodiment can include a plasma chamber 200, a first plasma generation unit 110, a second plasma generation unit 112, a first power supply unit 210, a second power supply unit 212, and a matching unit 214.

Within the plasma chamber 200, a space 202 may be formed through which gas 204 and 206 and plasma can pass. The beginning and middle portions of the space 202 may be implemented in a circular form to enable circulation, while the final portion may have a linear structure. The final end of the space 202 may be physical joined with the supply pipe 108 of the process chamber 100, and as a result, the plasma may be supplied to the process chamber 100 through the supply pipe 108.

An entrance 204 for introducing a gas 204 and an entrance 206 for introducing a gas 206 can be formed separately, as illustrated in FIG. 2, or just one entrance 204 can be formed with the other entrance 206 omitted. Here, the gas 204 and 206 can be of the same type.

The first plasma generation unit 110 may be formed in a middle portion of the plasma chamber 200, as illustrated in FIG. 2, and may generate a magnetic field to change the gas flowing through the space 202 into high-density plasma. According to an embodiment of the invention, the first plasma generation unit 110 can use a ferrite core induction method and can be provided with a power supply of a low frequency, for example within the range of 100 kHz to 600 kHz. More specifically, the first plasma generation unit 110 may be implemented by winding an induction coil 222 around a ferrite core 220 and arranging an insulator 224 around it. The first plasma generation unit 110 can be implemented such that it does not use a separate matching means and ignition means.

The output of the first plasma generation unit 110 can be in the form of a mixture of plasma and gas, and the plasma and gas may flow in the direction of the second plasma generation unit 112.

The second plasma generation unit 112 may be formed in a rear end portion of the plasma chamber 200, as illustrated in FIG. 2, and may generate a magnetic field to change the gas flowing through the space 202 into high-density plasma. According to an embodiment of the invention, the second plasma generation unit 112 can use an inductively coupled plasma method and can be provided with a power supply of a high frequency, for example within the range of 2 MHz to 13.56 MHz. The second plasma generation unit 112 may be implemented by winding an induction coil 232 around a plasma tube 230.

With the plasma generation units 110 and 112 installed in series as above, if one plasma generation unit 110 or 112 provides a low rate of change in changing a particular gas into plasma, the other plasma generation unit 112 or 110 can change the gas into plasma as much as desired. Thus, the plasma generation apparatus 102 can be used for every one of the deposition process, etching process, and cleaning process, even though these processes use different gases.

The matching unit 214 may be a device for matching the plasma tube 230 with a matching network such that a maximum amount of the power supply outputted from the power supply unit 212 is transmitted to the second plasma generation unit 112, and may perform matching to 50Ω, for example. In particular, as a high-frequency RF signal has properties similar to light, the plasma chamber 200 may not have a fixed impedance due to the presence of reflected waves, and such reflected waves may lower the efficiency of power transmission. In order to improve the efficiency of power transmission, the matching unit 214 can be designed to match both phase and magnitude, as described later on, and can employ a variable element.

Briefly put, a plasma generation apparatus 102 according to an embodiment of the invention may have the plasma generation units 110 and 112 installed in series to dually generate plasma, and thus may be a dual-mode plasma generation source. In particular, the plasma generation apparatus 102 can be installed with the plasma generation units 110 and 112, which can be applied for high frequency and low frequency, respectively, to allow application to every one of a deposition process, an etching process, a cleaning process, etc. While the present embodiment is described with the plasma generation apparatus 102 including two plasma generation units, it is also possible to include three or more plasma generation units. However, considering the size of the plasma generation apparatus 102, it may be desirable that the plasma generation apparatus 102 include two plasma generation units.

Although it was not described above, plasma may be generated initially by the second plasma generation unit 112 operating at a high frequency, and as the initially generated plasma is diffused into the plasma chamber 200, the plasma generation by the first plasma generation unit 110 can be facilitated. That is, even if the first plasma generation unit 110 uses a method with which it is not easy to generate plasma initially, there is no need for a separate device (a high-voltage plug, etc.) for the ignition of the first plasma generation unit 110. Whereas in the past a separate ignition element was needed for a plasma generation apparatus if a method was used that cannot generate plasma well at the initial stages, the first plasma generation unit 110 for a plasma generation apparatus 102 according to an embodiment of the invention does not require an ignition element. The initial ignition can be implemented by applying a high-frequency RF signal to the second plasma generation unit 112.

A detailed description of a matching unit 214 according to an embodiment of the invention is provided below with reference to the accompanying drawings.

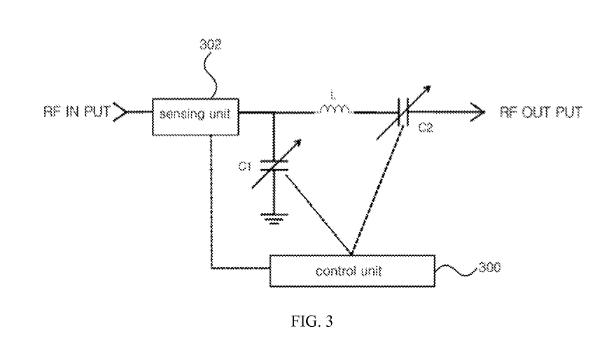

FIG. 3 illustrates a matching unit according to an embodiment of the invention.

Referring to FIG. 3, the matching unit 214 of this embodiment may include a control unit 300, a sensing unit 302, an inductor L, and two variable capacitors C1 and C2.

The sensing unit 302 may sense an RF signal provided from the power supply unit 212, especially its phase and magnitude, and may transmit the sensing results to the control unit 300.

The control unit 300 may adjust the capacitors C1 and C2 according to the transmitted sensing results such that the impedance of the output RF signal outputted from the matching unit 214 matches the impedance of the plasma chamber 200. Here, the capacitor C1 connected in parallel with the inductor L may perform matching for the phase, while the capacitor C2 connected in series with the inductor L may perform matching for the magnitude.

Briefly put, since the impedance of the plasma chamber 200 is not fixed, the matching unit 214 of the present embodiment may perform impedance matching according to the impedance of the plasma chamber 200 by adjusting the capacitances of the capacitors C1 and C2.

The embodiments of the invention described above are disclosed herein for illustrative purposes only. It is to be appreciated that various modifications, alterations, and additions can be made by those of ordinary skill in the art without departing from the technical spirit and scope of the invention, and that such modifications, alterations, and additions are encompassed by the scope of claims set forth below.

What is claimed is:

1. A multiple-mode plasma generation apparatus for supplying a plasma to a processing chamber, the multiple-mode plasma generation apparatus comprising:
a first plasma generation unit; and
a second plasma generation unit connected in series with the first plasma generation unit,
wherein a gas is changed to plasma by a magnetic field generated by the first plasma generation unit and the second plasma generation unit, the first plasma generation unit is operated by a low-frequency power supply, and the second plasma generation unit is operated by a high-frequency power supply.

2. The multiple-mode plasma generation apparatus of claim 1, wherein a working pressure of the first plasma generation unit is greater than a working pressure of the second plasma generation unit, and the plasma generation apparatus generates plasma for at least two of a deposition process, an etching process, and a cleaning process.

3. The multiple-mode plasma generation apparatus of claim 1, further comprising:
a plasma chamber configured to receive the gas and the plasma flowing therein;
a first power supply unit configured to provide power to the first plasma generation unit;
a second power supply unit configured to supply power to the second plasma generation unit; and
a matching unit configured to perform impedance matching between the second power supply unit and the second plasma generation unit,
wherein the matching unit comprises a first capacitor and a second capacitor, the first capacitor configured to match a phase of a power supply (RF signal) provided to the second plasma generation unit, the second capacitor configured to match a magnitude of the power supply provided to the second plasma generation unit, and wherein the first capacitor and the second capacitor are connected together in parallel with respect to an inductor.

4. The multiple-mode plasma generation apparatus of claim 3, wherein ignition is achieved by providing a high-frequency power supply to the second plasma generation unit, the plasma generated by the second plasma generation unit is diffused into the plasma chamber, a plasma generation of the first plasma generation unit is activated by the diffused plasma, and there is no separate ignition element for the first plasma generation unit formed on the plasma generation apparatus.

5. The multiple-mode plasma generation apparatus of claim 3, wherein an impedance of the plasma chamber is not constant, and the matching unit determines capacitances for the capacitors in consideration of the impedance of the plasma chamber.

6. The multiple-mode plasma generation apparatus of claim 1, further comprising:
a plasma chamber,
wherein the first plasma generation unit is implemented in a form of an induction coil wound around a ferrite core in a middle portion of the plasma chamber, and the second plasma generation unit is implemented in a form of an induction coil wound around a plasma tube in an end portion of the plasma chamber.

7. The multiple-mode plasma generation apparatus of claim 6, wherein a portion of a space of the plasma chamber corresponding to the first plasma generation unit has a circular shape and a portion of the space corresponding to the second plasma generation unit has a straight shape, and wherein a rear end of the second plasma generation unit is connected to a supply pipe of the processing chamber.

8. A multiple-mode plasma generation apparatus for supplying a plasma to a processing chamber, the multiple-mode plasma generation apparatus comprising:
a first plasma generation unit; and
a second plasma generation unit connected in series with the first plasma generation unit,
wherein a gas is changed to plasma by a magnetic field generated by the first plasma generation unit and the second plasma generation unit, and a working pressure of the first plasma generation unit is different from a working pressure of the second plasma generation unit.

9. The multiple-mode plasma generation apparatus of claim 8, further comprising:
a plasma chamber configured to receive the gas and the plasma flowing therein;
a first power supply unit configured to provide power to the first plasma generation unit;
a second power supply unit configured to supply power to the second plasma generation unit; and
a matching unit configured to perform impedance matching between the second power supply unit and the second plasma generation unit,
wherein the matching unit comprises a first capacitor and a second capacitor, the first capacitor configured to match a phase of a power supply provided to the second plasma generation unit, the second capacitor configured to match a magnitude of the power supply provided to the second plasma generation unit,
the first capacitor and the second capacitor are connected together in parallel with respect to an inductor, the first plasma generation unit is operated by a low-frequency power supply, the second plasma generation unit is operated by a high-frequency power supply, and the plasma generation apparatus generates plasma for at least two of a deposition process, an etching process, and a cleaning process.

10. A multiple-mode plasma generation apparatus for supplying a plasma to a processing chamber, the multiple-mode plasma generation apparatus comprising:
a plasma chamber;
a first plasma generation unit; and
a second plasma generation unit connected in series with the first plasma generation unit,
wherein a gas is changed to plasma by a magnetic field generated by the first plasma generation unit and the second plasma generation unit, the first plasma generation unit is implemented in a form of an induction coil wound around a ferrite core in a middle portion of the plasma chamber, and the second plasma generation unit is implemented in a form of an induction coil wound around a plasma tube in an end portion of the plasma chamber.

11. The multiple-mode plasma generation apparatus of claim 10, wherein a low-frequency power supply is applied to the first plasma generation unit, a high-frequency power supply is applied to the second plasma generation unit, and a matching unit is arranged between the second plasma generation unit and a power supply unit supplying the high-frequency power supply,
and wherein a capacitor of the matching unit is determined according to an impedance of the plasma chamber.

12. A multiple-mode plasma generation apparatus for supplying a plasma to a processing chamber, the multiple-mode plasma generation apparatus comprising:
a plasma chamber;
a first plasma generation unit; and
a second plasma generation unit connected in series with the first plasma generation unit,
wherein a gas is changed to plasma by a magnetic field generated by the first plasma generation unit and the second plasma generation unit, plasma generated by a power supply applied to the second plasma generation unit is diffused into the plasma chamber for an ignition for the plasma generation apparatus, a plasma generation by the first plasma generation unit is activated by the diffused plasma, and there is no separate ignition element present for the first plasma generation unit.

13. The multiple-mode plasma generation apparatus of claim 12, wherein a low-frequency power supply is applied to the first plasma generation unit, a high-frequency power supply is applied to the second plasma generation unit, and a matching unit is arranged between the second plasma generation unit and a power supply unit supplying the high-frequency power supply,
and wherein a capacitor of the matching unit is determined according to an impedance of the plasma chamber.
